(19) United States
(12) Patent Application Publication
(10) Pub. No.: US 2026/0361269 A1
(43) Pub. Date: Nov. 12, 2026

(54) INDUCTOR-CAPACITOR VOLTAGE-CONTROLLED OSCILLATOR WITH COMMON DRAIN VOLTAGE-CONTROLLED CURRENT SOURCE

(71) Applicant: Apple Inc., Cupertino, CA (US)

(72) Inventor: Omar E Elaasar, San Diego, CA (US)

(21) Appl. No.: 19/202,725

(22) Filed: May 8, 2025

(51) Int. Cl. H03B 5/12

(52) U.S. Cl. CPC H03B 5/1206; H03B 2200/004

(57) ABSTRACT

This disclosure is directed to a Complementary Metal-Oxide-Semiconductor Inductor-Capacitor Voltage-Controlled Oscillator (VCO). The VCO may include differential circuitry for generating an output signal. The VCO may include switches forming common drain current source circuitry. The VCO may increase a source voltage of the switches to increase a gate voltage of the switches that correspond to the output signal. As such, the VCO may generate the output signal with greater voltage swing amplitude compared to other VCOs having similar switches or switches with similar junction voltages, thereby improving a signal to noise ratio (SNR) of the output signal.

### BACKGROUND

The present disclosure relates generally to wireless communication, and more specifically to voltage-controlled oscillators of transmitter and/or receiver circuits.

In some applications, a voltage-controlled oscillator (VCO) may include current source circuitry and resonator circuitry, and a common-mode filter. The current source circuitry may generate a direct current (DC) signal based on receiving a bias voltage. The resonator circuitry may receive the DC signal from the current source circuitry and generate a VCO output signal based on the DC signal. For example, the resonator circuitry may generate the output signal with an oscillation frequency and voltage amplitude based on an inductive and/or capacitive value of components of the resonator circuitry and an electrical current value of the DC signal. It is desired to reduce undesired noise signals of the output signal.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, an electronic device may include one or more antennas and a voltage-controlled oscillator (VCO) coupled to the one or more antennas. The VCO may include a first inductor, a second inductor, and a first switch having a first terminal tapped onto a winding of the first inductor, a second terminal coupled to a first terminal of the first inductor, and a third terminal coupled to a first terminal of the second inductor.

In another embodiment, a voltage-controlled oscillator (VCO) may include a first inductor-capacitor tank coupled to a voltage source terminal, a first output terminal of the VCO, and a second output terminal of the VCO, a first switch having a first terminal coupled to the voltage source terminal and a second terminal coupled to the first output terminal, a second switch having a first terminal coupled to the voltage source terminal and a second terminal coupled to the second output terminal, and a second inductor-capacitor tank directly coupled to a third terminal of the first switch and a third terminal of the second switch.

In yet another embodiment, a transceiver may include a first inductor-capacitor tank coupled to a voltage source terminal, a first output terminal, and a second output terminal, a second inductor-capacitor tank, and a first switch having a first terminal coupled to the voltage source terminal, a second terminal coupled to the first output terminal, and a third terminal coupled to the second inductor-capacitor tank circuit.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is a block diagram an N-channel voltage-controlled oscillator (VCO) of the transmitter of FIG. 3 and/or the receiver of FIG. 4 having a common drain current source circuitry, according to embodiments of the present disclosure;

FIG. 6 is a schematic diagram of the N-channel VCO of FIG. 5, according to embodiments of the present disclosure;

FIG. 7 illustrates an example output signal of the N-channel VCO of FIGS. 5 and 6 having an increased voltage swing amplitude based on an increased voltage swing amplitude of the source terminals of N-channel switches of the N-channel VCO, according to embodiments of the present disclosure;

FIG. 8 is a block diagram a P-channel VCO of the transmitter of FIG. 3 and/or the receiver of FIG. 4 having a common drain current source circuitry, according to embodiments of the present disclosure;

FIG. 9 is a schematic diagram of the P-channel VCO of FIG. 8, according to embodiments of the present disclosure;

FIG. 10 illustrates an example output signal of the P-channel VCO of FIGS. 8 and 9 having an increased voltage swing amplitude based on an increased voltage swing amplitude of the source terminals of P-channel switches of the P-channel VCO, according to embodiments of the present disclosure;

FIG. 11 is an example layout of the VCO of FIGS. 3-10, according to embodiments of the present disclosure;

FIG. 12 illustrates inductors of the VCO of FIGS. 3-10 laid out in a concentric form, according to embodiments of the present disclosure; and

FIG. 13 illustrates inductors of the VCO of FIGS. 3-10 laid out in a partially overlapping form, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to a Complementary Metal-Oxide-Semiconductor Inductor-Capacitor Voltage-Controlled Oscillator, hereinafter referred to as a VCO, with improved (e.g., reduced) common-mode noises compared to other VCOs that do not include the disclosed embodiments. The VCO may generate an output signal (e.g., a differential output signal) with a desired oscillation frequency. The VCO may include differential circuitry for generating the output signal. If not compensated for, in some cases, the undesired common-mode noises may cause undesired voltage and/or frequency offsets around the output signal causing undesired flicker and/or phase noise of the output signal. In the embodiments discussed herein, the VCO may include common drain current source circuitry for generating the output signal with improved signal to noise ratio (SNR). Accordingly, the VCO may have reduced undesired flicker and/or phase noise and/or reduced undesired voltage and/or frequency offsets around the output signal.

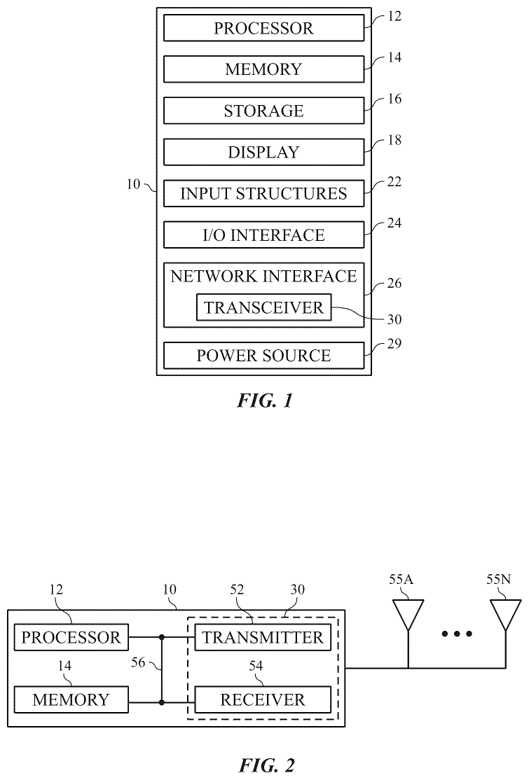

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH network, a local area network (LAN) or wireless local area network (WLAN), such as a network employing one of the IEEE 802.11x family of protocols (e.g., WI-FI), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, Long Term Evolution (LTE) cellular network, Long Term Evolution License Assisted Access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX), mobile broadband Wireless networks (mobile WIMAX®), asynchronous digital subscriber lines (e.g., ADSL, VDSL), digital video broadcasting-terrestrial (DVB-T) network and its extension DVB Handheld (DVB-H) network, ultra-wideband (UWB) network, alternating current (AC) power lines, and so forth.

As illustrated, the network interface 26 may include a transceiver or modem 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of power, such as a rechargeable lithium polymer (Li-poly) battery and/or an alternating current (AC) power converter.

FIG. 2 is a functional diagram of the electronic device 10 of FIG. 1, according to embodiments of the present disclosure. As illustrated, the processor 12, the memory 14, the transceiver 30, a transmitter or wireless transmission circuitry 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

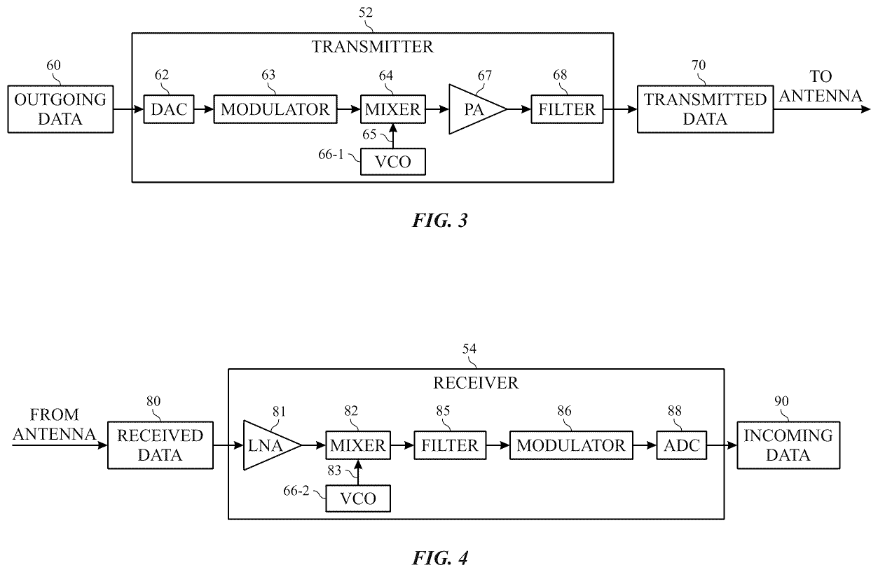

FIG. 3 is a schematic diagram of the transmitter 52 (e.g., transmit circuitry, the wireless transmission circuitry), according to embodiments of the present disclosure. As illustrated, the transmitter 52 may receive outgoing data 60 in the form of a digital signal to be transmitted via the one or more antennas 55. A digital-to-analog converter 62 of the transmitter 52 may convert the digital signal to an analog signal.

A modulator 63 may combine the converted analog signal with a carrier signal to generate a radio wave. A mixer 64 may combine the carrier signal with a local oscillator signal 65 to generate a radio frequency signal (e.g., a combined signal). The VCO 66-1 (e.g., a local oscillator) may generate the local oscillator signal 65 having an oscillation frequency (e.g., a carrier frequency). In additional or alternative embodiments, the VCO 66-1 may generate the carrier signal having the carrier frequency (e.g., the oscillation frequency).

A power amplifier 67 receives the modulated signal from the mixer 64. The power amplifier 67 may amplify the modulated signal to a suitable level to drive transmission of the signal via the one or more antennas 55. A filter 68 (e.g., filter circuitry and/or software) of the transmitter 52 may then remove undesirable noise from the amplified signal to generate transmitted signal 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter.

Although the transmitter 52 is shown to include a single VCO 66-1, it should be appreciated that the electronic device 10 and/or the transmitter 52 may include additional VCOs 66-1. In different embodiments, the additional VCOs 66-1 may perform different operations of the electronic device 10 and/or the transmitter 52, such as frequency synthesis applications and clock generation applications. Furthermore, the power amplifier 67 and/or the filter 68 may be referred to as part of a radio frequency front end (RFFE), and more specifically, a transmit front end of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include additional mixers and/or VCOs 66-1. As another example, the transmitter 52 may not include the filter 68 if the power amplifier 67 outputs the amplified signal in or approximately in a desired frequency range (such that filtering of the amplified signal may be unnecessary).

FIG. 4 is a schematic diagram of the receiver 54 (e.g., receive circuitry), according to embodiments of the present disclosure. As illustrated, the receiver 54 may receive received signal 80 from the one or more antennas 55 in the form of an analog signal. A low noise amplifier 81 may amplify the received analog signal to a suitable level for the receiver 54 to process. A mixer 82 may combine (e.g., mix) the amplified signal with a local oscillator signal 83 to generate an intermediate frequency signal or a baseband frequency signal (e.g., a combined signal). A VCO 66-2 (e.g., a second VCO, a local oscillator) may generate the local oscillator signal 83 with an oscillation frequency, such as an intermediate frequency or baseband frequency, for down conversion of a frequency of the incoming RF signal for processing.

A filter 85 (e.g., filter circuitry and/or software) may remove undesired noise from the received signal 80, such as cross-channel interference. The filter 85 may also remove additional signals received by the one or more antennas 55 that are at frequencies other than the desired signal. The filter 85 may include any suitable filter or filters to remove the undesired noise or signals from the received signal 80, such as a bandpass filter, a bandstop filter, a low pass filter, a high pass filter, and/or a decimation filter. The low noise amplifier 81 and/or the filter 85 may be referred to as part of the RFFE, and more specifically, a receiver front end of the electronic device 10.

A demodulator 86 may remove a radio frequency carrier signal and/or extract a demodulated signal (e.g., an envelope signal) from the filtered signal for processing. In some embodiments, the demodulator 86 may receive a signal indicating a frequency and phase of the received signal 80 and/or the intermediate frequency or baseband frequency from the VCO 66-2 to generate the remove a radio frequency carrier signal and/or extract a demodulated signal (e.g., an envelope signal) from the filtered signal for processing. An analog-to-digital converter 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received signal 80 via the one or more antennas 55. For example, the receiver 54 may include additional mixers and/or VCOs 66-2.

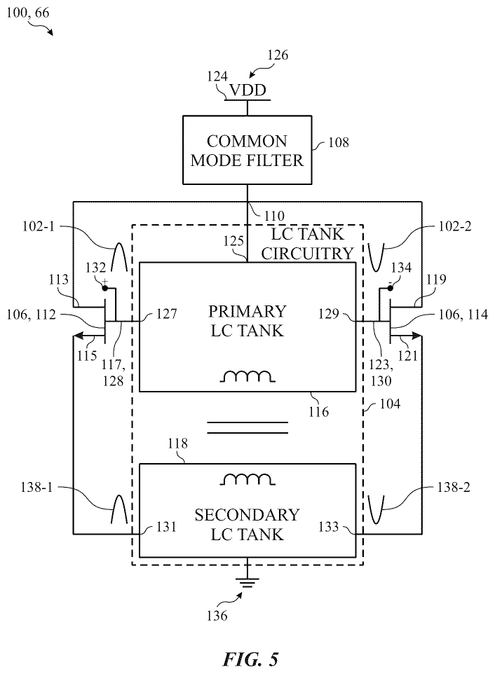

FIG. 5 is a block diagram of components of an N-channel VCO 100 of the transmitter 52 and/or the receiver 54 that may generate an output signal 102, according to embodiments of the present disclosure. The transmitter 52 and/or the receiver 54 discussed above may include the N-channel VCO 100. For example, the VCOs 66-1 and 66-2 may be collectively referred to as the VCO 66. Moreover, the N-channel VCO 100 may correspond to one embodiment of a VCO 66.

The output signal 102 may include a differential output signal having a first output signal component 102-1 (e.g., a first signal, a positive signal) and a second output signal component 102-2 (e.g., a second signal, a negative signal). The first output signal component 102-1 and the second output signal component 102-2 may be collectively referred to as the output signal 102. In some embodiments, the output signal 102 may correspond to the local oscillator signal 65 and/or 83 discussed above.

The N-channel VCO 100 may include inductor-capacitor (LC) tank circuitry 104 (e.g., differential resonator circuitry), N-channel current source circuitry 106 (e.g., common drain voltage-controlled current source circuitry), and a common-mode filter 108 (e.g., common-mode resonator, a tail filter). It should be appreciated that in some embodiments, the N-channel VCO 100 may include alternative or additional circuitry and/or components such as a decoupling network, among other things.

The N-channel current source circuitry 106 may include a first N-channel switch 112 (e.g., a first N-channel metal-oxide semiconductor (NMOS) switch) and a second N-channel switch 114 (e.g., a second NMOS switch). A drain terminal 113 (e.g., a first terminal) of the first N-channel switch 112 may be coupled to a drain terminal 119 (e.g., a first terminal) of the second N-channel switch 114 via a first node 110 forming a common drain voltage-controlled current source. It should be appreciated that in alternative or additional embodiments, the N-channel current source circuitry 106 may include different switches, such as any viable transistor, and/or a different number of switches forming the common drain voltage-controlled current source.

The LC tank circuitry 104 may include a primary LC tank 116 and a secondary LC tank 118. The primary LC tank 116 may inductively couple to the secondary LC tank 118 during an operation of the N-channel VCO 100. The drain terminals 113 and 119 of the first N-channel switch 112 and the second N-channel switch 114 may be coupled to a first terminal 125 of the primary LC tank 116 via the first node 110. Moreover, the drain terminals 113 and 119 of the first N-channel switch 112 and the second N-channel switch 114 and the first terminal 125 of the primary LC tank 116 may be coupled to the power source terminal 124 via (e.g., through) the common-mode filter 108.

The drain terminals 113 and 119 of the first N-channel switch 112 and the second N-channel switch 114 and the first terminal 125 of the primary LC tank 116 may receive a bias voltage 126 (e.g., VDD, a direct current (DC) signal) via the power source terminal 124. In some embodiments, the power source 29 discussed above may be coupled to the power source terminal 124. In some cases, the power source 29 may generate and/or output the bias voltage 126. Alternatively or additionally, the N-channel VCO 100 may receive the bias voltage 126 from any other viable circuit. Moreover, the first N-channel switch 112, the second N-channel switch 114, and/or the primary LC tank 116 may receive any other viable input signal in lieu or additional to the bias voltage 126.

The common-mode filter 108 may include one or more capacitors and inductors. In some cases, the common-mode filter 108 may reduce voltage fluctuations of the bias voltage 126 and/or one or more noises and/or harmonics of the N-channel VCO 100. The common-mode filter 108 may provide a low impedance (e.g., a relative short circuit connection, approaching a short circuit impedance or resistance, near-zero or zero impedance or resistance, and so on) to the bias voltage 126. As such, N-channel current source circuitry 106 and the LC tank circuitry 104 may receive the bias voltage 126 from the common-mode filter 108.

For example, the common-mode filter 108 may have a resonant frequency range associated with the undesired common-mode noises. As such, the common-mode filter 108 may reduce (e.g., suppress) the undesired common-mode noises of the output signal 102 while providing a relatively short circuit path to the bias voltage 126, the DC signal, and the output signal 102. In some cases, the resonant frequency range may correspond to a frequency range associated with one or more harmonics (e.g., integer multiples) of the output signal 102.

The N-channel current source circuitry 106 may be differentially coupled to the primary LC tank 116 via a second node 128 and a third node 130. In the depicted embodiment, a gate terminal 117 (e.g., a second terminal) of the first N-channel switch 112 may be coupled to a second terminal 127 of the primary LC tank 116 via the second node 128. Moreover, a gate terminal 123 (e.g., a second terminal) of the second N-channel switch 114 may be coupled to a third terminal 129 of the primary LC tank 116 via the third node 130. The second node 128 may correspond to (e.g., include, be coupled to) a positive output terminal 132 and the third node 130 may correspond to (e.g., include, be coupled to) a negative output terminal 134 of the N-channel VCO 100. The second terminal 127 and the third terminal 129 of the primary LC tank 116 may output the output signal 102 via the positive output terminal 132 and the negative output terminal 134.

A source terminal 115 (e.g., a third terminal) of the first N-channel switch 112 may be coupled to a first terminal 131 of the secondary LC tank circuit 118. A source terminal 121 (e.g., a third terminal) of the second N-channel switch 114 may be coupled to a second terminal 133 of the secondary LC tank circuit 118. The secondary LC tank 118 may be coupled to a ground terminal 136. The ground terminal 136 may have a ground voltage equal to zero volts, near zero volts, approximately zero volts, and/or a virtual ground voltage value, among other possibilities. Moreover, as mentioned above, the primary LC tank 116 may inductively couple to the secondary LC tank 118 during an operation of the N-channel VCO 100.

The N-channel current source circuitry 106 may generate and/or provide a DC signal based on receiving the bias voltage 126. For example, the first N-channel switch 112 and the second N-channel switch 114 may form the common drain voltage-controlled current source to generate and/or output the DC signal (e.g., a desired electrical current). The DC signal may have an oscillation frequency of zero, near zero, approximately zero, relatively zero, and/or below a threshold frequency. The LC tank circuitry 104 may generate the output signal 102 and an induced signal 138 (e.g., a first induced signal) based on receiving the DC signal and/or the bias voltage 126. The output signal 102 and the induced signal 138 may have an oscillation frequency within a resonant frequency range (e.g., a desired oscillation frequency range) of the LC tank circuitry 104.

The primary LC tank 116 may provide the first output signal component 102-1 to the gate terminal 117 of the first N-channel switch 112 and the positive output terminal 132 via the second node 128. The primary LC tank 116 may provide the second output signal component 102-2 to the gate terminal 123 of the second N-channel switch 114 and the negative output terminal 134 via the third node 130. In some embodiments, the LC tank circuitry 104 may generate the output signal 102 with an oscillation frequency corresponding to a carrier signal having the carrier frequency for transmitting outgoing data 60 discussed above. In alternative or additional embodiments, the LC tank circuitry 104 may generate the output signal 102 with an oscillation frequency corresponding to an intermediate or baseband oscillating signal for down-conversion and/or processing of the received signal 80 discussed above.

The primary LC tank 116 may induce the signal 138 in the secondary LC tank circuit 118. The induced signal 138 (e.g., induced voltage) may include a differential output signal having a first induced signal component 138-1 (e.g., a first signal, a positive signal) and a second induced signal component 138-2 (e.g., a second signal, a negative signal). The secondary LC tank circuit 118 may provide the first induced signal component 138-1 to the source terminal 115 of the first N-channel switch 112. Moreover, the secondary LC tank circuit 118 may provide the second induced signal component 138-2 to the source terminal 121 of the second N-channel switch 114. The first induced signal component 138-1 and the second induced signal component 138-2 may be collectively referred to as the induced signal 138.

The primary LC tank 116 and the secondary LC tank circuit 118 may each include one or more inductors and/or capacitors to synchronize the induced signal 138 with the output signal 102. As such, the primary LC tank 116 may induce a portion of the voltage swing amplitude of the gate terminals 117 and 123 of the N-channel switches 112 and 114 in the respective source terminals 115 and 121. Accordingly, the induced signal 138 may increase voltage swing amplitudes at the source terminals 115 and 121 of the N-channel switches 112 and 114 based on voltage swing amplitudes of the output signal 102 at the respective gate terminals 117 and 123.

For example, a voltage swing amplitude of the induced signal 138 may correspond to a fraction of a voltage swing amplitude of the output signal 102. The fraction of the output signal 102 may correspond to one-eighth or less, a quarter or less, one-third or less, or half or greater or less of the output signal 102. An oscillation frequency of the induced signal 138 may correspond to an oscillation frequency of the output signal 102. A phase of the first induced signal component 138-1 may correspond to a phase of the first output signal component 102-1. Moreover, a phase of the second induced signal component 138-2 may correspond to a phase of the second output signal component 102-2. Accordingly, the induced signal 138 may increase voltage swing amplitudes of the source terminals 115 and 121 of the N-channel switches 112 and 114 in synchronization with the output signal 102 at the gate terminals 117 and 123 of the N-channel switches 112 and 114.

With the foregoing in mind, junction voltages (e.g., V_{GS}) of the N-channel switches 112 and 114 may correspond to a differential voltage between voltage swing amplitudes of the respective gate terminals 117 and 123 and source terminals 115 and 121. Moreover, the N-channel switches 112 and 114 may have a junction voltage threshold. The junction voltage threshold of the N-channel switches 112 and 114 may correspond to 0.1 volts (V) or less, 0.37 V or less, 0.45 V or less, 0.7 V or less, 1 V or greater or less, and so on, among other possibilities. In the depicted embodiment, a differential voltage between the output signal 102 at the gate terminals 117 and 123 and the induced signal 138 at the source terminals 115 and 121 of the N-channel switches 112 and 114 may be equal to or less than the junction voltage threshold. For example, a voltage value (e.g., an instantaneous voltage value) of the output signal 102 at the gate terminals 117 and 123 of the N-channel switches 112 and 114 may correspond to a cumulative value (e.g., an instantaneous cumulative value, an immediate cumulative value) of a voltage swing amplitude of the induced signal 138 and the differential voltage (e.g., the respective junction voltage, V_{GS}).

As discussed above, the induced signal 138 may increase voltage swing amplitudes of the source terminals 115 and 121 of the N-channel switches 112 and 114 in synchronization with the output signal 102 at the gate terminals 117 and 123 of the N-channel switches 112 and 114. As such, the voltage swing amplitude of the output signal 102 may be increased without increasing (e.g., expanding) or exceeding (e.g., violating) the junction voltage (e.g., V_{GS}) of the N-channel switches 112 and 114 based on the increased voltage swing amplitude of the respective source terminal 115 and 121. For example, a gate voltage of the first N-channel switch 112 may be increased greater than gate voltages of other VCOs without increasing or exceeding a first junction voltage (e.g., V_{GS1}) of the first N-channel switch 112 based on the induced voltage on the respective source terminal 115 and 121. Similarly, the gate voltage of the second N-channel switch 114 may be increased greater than voltage amplitudes of other VCOs without increasing or exceeding a second junction voltage (e.g., V_{GS2}) of the second N-channel switch 114 based on the induced voltage on the respective source terminal 115 and 121.

Accordingly, the N-channel VCO 100 may generate and/or output the output signal 102 with a greater voltage swing amplitude compared to other VCOs having voltage-controlled current source switches with junction voltages similar (e.g., equal, nearly equal) to that of the N-channel switches 112 and 114. Moreover, the N-channel VCO 100 may have reduced undesired common-mode noises and improved SNR compared to the other VCOs. The common-mode noises may include a phase noise and/or a flicker noise, among other possibilities. For example, the N-channel VCO 100 may have an increased and/or expanded bandwidth for generating the output signal 102 based on the reduced undesired common-mode noises and/or the improved SNR. As mentioned above, in some embodiments, the common-mode filter 108 may be coupled to the power source terminal 124 and to the drain terminals 113 and 119 of the N-channel switches 112 and 114 to reduce the undesired common-mode noises and improve the SNR.

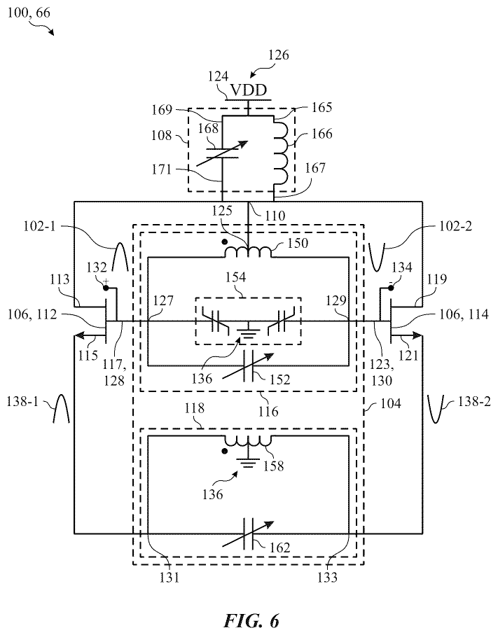

FIG. 6 is a schematic diagram of the N-channel VCO 100, according to embodiments of the present disclosure. In the depicted embodiment, the primary LC tank 116 may include a first inductor 150, a first variable capacitor 152 (e.g., a varactor), and a capacitor bank 154 including a number of capacitors. The secondary LC tank 118 may include a second inductor 158 and a second variable capacitor 162 (e.g., a varactor). Additionally or alternatively, the primary LC tank 116 and/or the secondary LC tank 118 may include switched capacitor circuitry and/or additional capacitor banks, among other things. Moreover, as mentioned above, the N-channel current source circuitry 106 may include the first N-channel switch 112 and the second N-channel switch 114.

The common-mode filter 108 may include a tail inductor 166 (e.g., a first degeneration inductor) and a tail capacitor 168 (e.g., a degeneration capacitor, a variable degeneration capacitor). The tail inductor 166 and/or the tail capacitor 168 may reduce noise of the bias voltage 126 from the voltage terminal 124 to the LC tank circuitry 104 and/or the N-channel current source circuitry 106. Alternatively or additionally, the tail inductor 166 and/or the tail capacitor 168 may reduce noise of the N-channel VCO 100 at the voltage terminal 124. A first terminal 165 of the tail inductor 166 and a first terminal 169 of the tail capacitor 168 may be coupled to the power source terminal 124. A second terminal 167 of the tail inductor 166 and a second terminal 171 of the tail capacitor 168 may be coupled to the first inductor 150, the drain terminal 113 of the first N-channel switch 112, and the drain terminal 119 of the second N-channel switch 114.

As mentioned above, the drain terminals 113 and 119 of the N-channel switches 112 and 114 and the first terminal 125 of the primary LC tank 116 may be coupled to the power source terminal 124 via (e.g., through) the common-mode filter 108. The first terminal 125 of the primary LC tank 116 may correspond to or be disposed on a winding of the first inductor 150. In the depicted embodiment, the second terminals 167 and 171 of the tail inductor 166 and the tail capacitor 168 may be coupled to drain terminals 113 and 119 of the N-channel switches 112 and 114 and tapped onto (e.g., coupled to) the winding of the first inductor 150.

In some embodiments, the tail inductor 166 and the tail capacitor 168 may be tapped onto a center tap of the first inductor 150 dividing the first inductor 150 into two split (e.g., halved) inductors. Alternatively or additionally, the first decoupling inductor 156 may be tapped onto any other part or portion of the first inductor 150. The first inductor 150 may be coupled to the power source terminal 124 via the tail inductor 166 (e.g., a degeneration inductor) and the tail capacitor 168.

First terminals of the first inductor 150, the first variable capacitor 152, and the capacitor bank 154 may be coupled to the gate terminal 117 of the first N-channel switch 112 via the second node 128. Second terminals of the first inductor 150, the first variable capacitor 152, and the capacitor bank 154 may be coupled to the gate terminal 123 of the second N-channel switch 114 via the third node 130. As mentioned above, the second node 128 may correspond to (e.g., include, be coupled to) a positive output terminal 132 and the third node 130 may correspond to (e.g., include, be coupled to) a negative output terminal 134 of the N-channel VCO 100.

The second inductor 158 may be coupled to the ground terminal 136. In the depicted embodiment, the ground terminal 136 may be tapped onto a winding of the second inductor 158. For example, the ground terminal 136 may be tapped onto a center tap of the second inductor 158 dividing the second inductor 158 into two split (e.g., halved) inductors. Alternatively or additionally, the ground terminal 136 may be tapped onto any other part or portion of the second inductor 158. First terminals of the second inductor 158 and the second variable capacitor 162 may be coupled to the source terminal 115 of the first N-channel switch 112. Second terminals of the second inductor 158 and the second variable capacitor 162 may be coupled to the source terminal 121 of the second N-channel switch 114.

The first inductor 150 and the second inductor 158 may inductively couple with a coupling factor (K) equal to or greater than a first threshold for signals having an oscillation frequency within the resonant frequency range of the LC tank circuitry 104. For example, the signals may include the output signal 102 being generated by the LC tank circuitry 104 and may have an oscillation frequency within the resonant frequency range of the LC tank circuitry 104, among other possibilities. The first threshold may be 0.3 or less or greater, 0.4 or greater, 0.44 or greater, 0.5 or greater, 0.72 or greater, 0.76 or greater, 0.9 or greater, or 1, among other possibilities. In different embodiments, the first inductor 150 and the second inductor 158 may have different dimensions corresponding to the resonant frequency range of the LC tank circuitry 104. As such, the first inductor 150 may inductively couple to the second inductor 158 forming a transformer to generate or provide the output signal 102 having an oscillation frequency within the resonant frequency range of the LC tank circuitry 104.

For example, the first inductor 150 may induce the signal 138 in the second inductor 158 and/or the secondary LC tank 118. As discussed above, the induced signal 138 may increase voltage swing amplitudes of the source terminals 115 and 121 of the N-channel switches 112 and 114 in synchronization with the output signal 102 at the gate terminals 117 and 123 of the N-channel switches 112 and 114. As such, the voltage swing amplitude of the output signal 102 may be increased greater than the voltage swing amplitudes of output signals of other VCOs having voltage-controlled current source switches with similar (e.g., equal, nearly equal) junction voltages. Moreover, the N-channel VCO 100 may have reduced undesired common-mode noises and improved SNR compared to the other VCOs based on the increased voltage swing amplitude of the output signal 102.

The first inductor 150 and the second inductor 158 may inductively uncouple for signals having an oscillation frequency outside the resonant frequency range of the LC tank circuitry 104 based on a coupling factor equal to or less than a second threshold. The signals may be generated and/or received by the LC tank circuitry 104 and may have the undesired oscillation frequency outside the resonant frequency range of the LC tank circuitry 104. For example, the signals may include the common-mode noises, among other possibilities. The second threshold may be 1 or less, 0.9 or less, 0.85 or less, 0.72 or less, 0.64 or less, 0.5 or less, 0.4 or less, 0.2 or less, 0.1 or less, or 0.05 or less, among other possibilities. As such, the first inductor 150 and the second inductor 158 may inductively uncouple for the common-mode noises having the undesired oscillation frequency outside the resonant frequency range of the LC tank circuitry 104. Accordingly, the first inductor 150 and the second inductor 158 may at least partly uncouple and/or isolate the primary LC tank 116 from the secondary LC tank 118 for the common-mode noises.

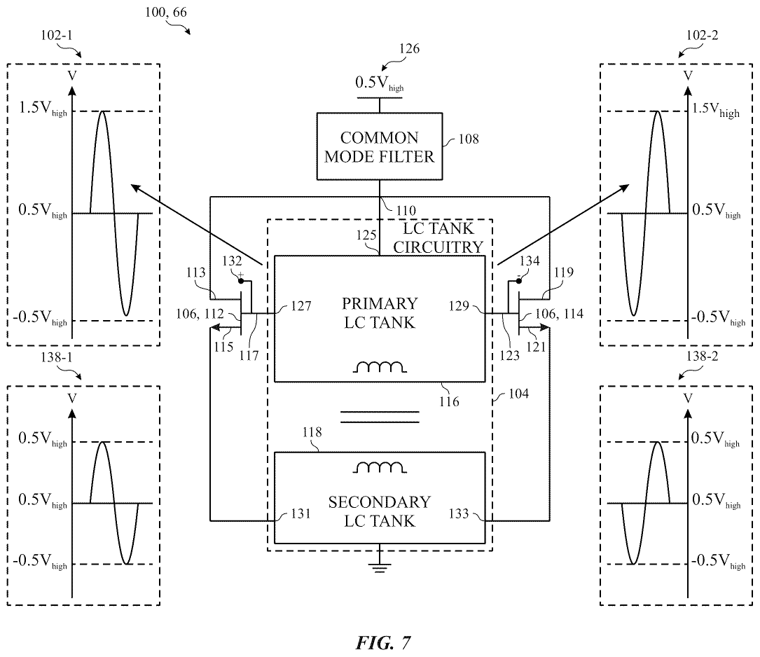

FIG. 7 illustrates an example output signal 102 of the N-channel VCO 100 having an increased voltage swing amplitude based on an increased voltage swing amplitude of the source terminals 115 and 121 of the N-channel switches 112 and 114, according to embodiments of the present disclosure. As discussed above, the first N-channel switch 112 and the second N-channel switch 114 may form the common drain voltage-controlled current source. For example, the N-channel current source circuitry 106 may generate and/or provide a DC signal based on receiving the bias voltage 126. Moreover, the LC tank circuitry 104 may generate the output signal 102 and the induced signal 138 based on receiving the DC signal and/or the bias voltage 126. The output signal 102 may include the first output signal component 102-1 and the second output signal component 102-2. The induced signal 138 may include the first induced signal component 138-1 and the second induced signal component 138-2.

The primary LC tank 116 may provide the first output signal component 102-1 to the positive output terminal 132 and provide the second output signal component 102-2 to the negative output terminal 134. The secondary LC tank circuit 118 may provide the first induced signal component 138-1 to the source terminal 115 of the first N-channel switch 112. Moreover, the secondary LC tank circuit 118 may provide the second induced signal component 138-2 to the source terminal 121 of the second N-channel switch 114. The induced signal 138 may increase voltage swing amplitudes at the source terminals 115 and 121 of the N-channel switches 112 and 114 based on voltage swing amplitudes of the output signal 102 at the respective gate terminals 117 and 123.

For example, a voltage swing amplitude of the first induced signal component 138-1 may correspond to a fraction (e.g., one-eighth or less, a quarter or less, one-third or less, or half or greater or less) of a voltage swing amplitude of the first output signal component 102-1. As such, the primary LC tank 116 may induce a portion of the voltage swing amplitude of the gate terminal 117 of the first N-channel switch 112 in the source terminal 115 of the first N-channel switch 112. Moreover, a voltage swing amplitude of the second induced signal component 138-2 may correspond to a fraction (e.g., one-eighth or less, a quarter or less, one-third or less, or half or greater or less) of a voltage swing amplitude of the second output signal component 102-2. Accordingly, the primary LC tank 116 may induce a portion of the voltage swing amplitude of the gate terminal 123 of the second N-channel switch 114 in the source terminal 121 of the second N-channel switch 114.

An oscillation frequency of the induced signal 138 may correspond to the oscillation frequency of the output signal 102. A phase of the first induced signal component 138-1 may correspond to that of the first output signal component 102-1. A phase of the second induced signal component 138-2 may correspond to that of the second output signal component 102-2. As such, the induced signal 138 may increase voltage swing amplitudes of the source terminals 115 and 121 of the N-channel switches 112 and 114 in synchronization with the output signal 102 at the gate terminals 117 and 123 of the N-channel switches 112 and 114.

With the foregoing in mind, the first junction voltage (e.g., V_{GS1}) of the first N-channel switch 112 may correspond to a differential voltage between voltage swing amplitudes of the gate terminal 117 and the source terminal 115 of the first N-channel switch 112. Moreover, the second junction voltage (e.g., V_{GS2}) of the second N-channel switch 114 may correspond to a differential voltage between voltage swing amplitudes of the gate terminal 123 and the source terminal 121 of the second N-channel switch 114. The N-channel switches 112 and 114 may each have a junction voltage threshold associated with the respective junction voltages. The first junction voltage threshold of the first N-channel switch 112 and the second junction voltage threshold of the second N-channel switch 114 may each correspond to 0.1 V or less, 0.37 V or less, 0.45 V or less, 0.7 V or less, 1 V or less, and so on, among other possibilities.

The first junction voltage (e.g., V_{GS1}) of the first N-channel switches 112 may not exceed the first junction voltage threshold. Moreover, the first induced signal component 138-1 may increase voltage swing amplitude of the source terminal 115 of the first N-channel switch in synchronization with the first output signal component 102-1 at the gate terminal 117 of the first N-channel switch 112. As such, the voltage swing amplitude of the first output signal component 102-1 may be increased without increasing (e., expanding) or exceeding (e.g., violating) the first junction voltage (e.g., V_{GS1}). For example, the voltage swing amplitude of the first output signal component 102-1 may be increased by a voltage value corresponding to the voltage value (e.g., an instantaneous voltage value) of the first induced signal component 138-1.

The second junction voltage (e.g., V_{GS2}) of the second N-channel switches 114 may not exceed the second junction voltage threshold. Moreover, the second induced signal component 138-2 may increase voltage swing amplitude of the source terminal 121 of the second N-channel switch in synchronization with the second output signal component 102-2 at the gate terminal 123 of the second N-channel switch 114. As such, the voltage swing amplitude of the second output signal component 102-2 may be increased without increasing (e., expanding) or exceeding (e.g., violating) the second junction voltage (e.g., V_{GS2}). For example, the voltage swing amplitude of the second output signal component 102-2 may be increased by a voltage value corresponding to the voltage value (e.g., an instantaneous voltage value) of the second induced signal component 138-2.

In the depicted embodiment, the bias voltage 126 may have a first voltage value of 0.5 V_{high}. V_{high} (or 1 V_{high}) may correspond to junction voltage thresholds of the N-channel switches 112 and 114. For example, the junction voltage (e.g., V_{GS1}, V_{GS2}) and/or a differential voltage between voltage swing amplitudes of the gate terminals 117 and 123 and the respective source terminals 115 and 121 of the N-channel switches 112 and 114 may be equal to or less than V_{high} (or 1 V_{high}). Other VCOs having voltage-controlled current source switches (e.g., common source voltage-controlled current source switches) with similar (e.g., equal, nearly equal) junction voltages may generate the output signal 102 with a voltage swing amplitude between 1 V_{high} and 0 V_{high}. The N-channel VCO 100 may generate the output signal 102 with a voltage swing amplitude between 1.5 V_{high} and −0.5 V_{high}. That is, the N-channel VCO 100 may generate the output signal 102 with an increased voltage swing amplitude and/or expanded (e.g., doubled) voltage swing amplitude range.

By way of example, the LC tank circuitry 104 may generate the first induced signal component 138-1 and the second induced signal component 138-2 having a voltage swing amplitude of 1 V_{high} between a low voltage swing amplitude of −0.5 V_{high} (e.g., an inverse of the first voltage value) and a high voltage swing amplitude of 0.5 V_{high} swinging around (e.g., centered at) 0 V_{high}. The first induced signal component 138-1 may be inversed compared to the second induced signal component 138-2. Moreover, the LC tank circuitry 104 may generate the first output signal component 102-1 and the second output signal component 102-2 having a voltage swing amplitude of 2 V_{high} (e.g., instead of 1 V_{high}) between a low voltage swing amplitude of −0.5 V_{high} (e.g., an inverse of the first voltage value) and a high voltage swing amplitude of 1.5 V_{high} swinging around (e.g., centered at) the first voltage value (e.g., 0.5 V_{high}).

The first induced signal component 138-1 may be in-phase (e.g., nearly in-phase) with the first output signal component 102-1. Moreover, the second induced signal component 138-2 may be in-phase (e.g., nearly in-phase) with the second output signal component 102-2. Accordingly, the N-channel VCO 100 may generate and/or output the output signal 102 with a greater voltage swing amplitude, reduced undesired common-mode noises, improved SNR, and/or increased and/or expanded bandwidth compared to other VCOs.

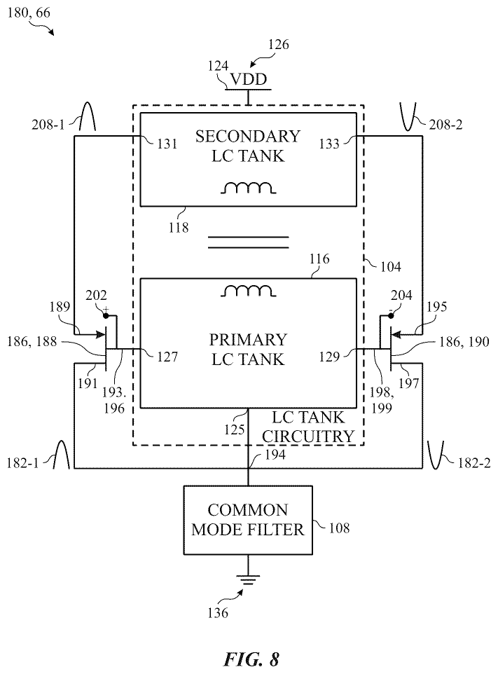

FIG. 8 is a block diagram of components of a P-channel VCO 180 of the transmitter 52 and/or the receiver 54 that may generate an output signal 182, according to embodiments of the present disclosure. The transmitter 52 and/or the receiver 54 discussed above may include the P-channel VCO 180. For example, the P-channel VCO 180 may correspond to one embodiment of the VCO 66.

The output signal 182 may include the differential output signal having a first output signal component 182-1 (e.g., a first signal, a positive signal) and a second output signal component 182-2 (e.g., a second signal, a negative signal). The first output signal component 182-1 and the second output signal component 182-2 may be collectively referred to as the output signal 182. In some embodiments, the output signal 182 may correspond to the local oscillator signal 65 and/or 83 discussed above.

The P-channel VCO 180 may include the LC tank circuitry 104 (e.g., the differential resonator circuitry), the P-channel current source circuitry 186 (e.g., common drain voltage-controlled current source circuitry), and the common-mode filter 108 (e.g., the common-mode resonator, the tail filter). It should be appreciated that in some embodiments, the P-channel VCO 180 may include alternative or additional circuitry and/or components such as a decoupling network, among other things.

The P-channel current source circuitry 186 may include a first P-channel switch 188 (e.g., a first P-channel metal-oxide semiconductor (PMOS) switch) and a second P-channel switch 190 (e.g., a second PMOS switch). A drain terminal 191 (e.g., a third terminal) of the first P-channel switch 188 may be coupled to a drain terminal 197 (e.g., a third terminal) of the second P-channel switch 190 via a first node 194 forming a common drain voltage-controlled current source. It should be appreciated that in alternative or additional embodiments, the P-channel current source circuitry 186 may include different switches, such as any viable transistor, and/or a different number of switches forming the common drain voltage-controlled current source.

The LC tank circuitry 104 may include the primary LC tank 116 and the secondary LC tank 118. The primary LC tank 116 may inductively couple to the secondary LC tank 118 during an operation of the P-channel VCO 180. The drain terminals 191 and 197 of the first P-channel switch 188 and the second P-channel switch 190 may be coupled to the first terminal 125 of the primary LC tank 116 via the first node 194. Moreover, the drain terminals 191 and 197 of the first P-channel switch 188 and the second P-channel switch 190 and the first terminal 125 of the primary LC tank 116 may be coupled to the ground terminal 136 via (e.g., through) the common-mode filter 108. The drain terminals 191 and 197 of the first P-channel switch 188 and the second P-channel switch 190 and the first terminal 125 of the primary LC tank 116 may receive the ground voltage via the ground terminal 136.

The common-mode filter 108 may include one or more capacitors and inductors. In some cases, the common-mode filter 108 may reduce voltage fluctuations of the bias voltage 126 and/or one or more noises and/or harmonics of the P-channel VCO 180. The common-mode filter 108 may provide a low impedance (e.g., a relative short circuit connection, approaching a short circuit impedance or resistance, near-zero or zero impedance or resistance, and so on) to the bias voltage 126. As such, P-channel current source circuitry 186 and the LC tank circuitry 104 may receive the bias voltage 126 from the common-mode filter 108.

For example, the common-mode filter 108 may have the resonant frequency range associated with the undesired common-mode noises. As such, the common-mode filter 108 may reduce (e.g., suppress) the undesired common-mode noises of the output signal 182 while providing a relatively short circuit path to the bias voltage 126, a DC signal, and the output signal 182. In some cases, the resonant frequency range of the common-mode filter 108 may correspond to a frequency range associated with one or more harmonics (e.g., integer multiples) of the output signal 182.

The P-channel current source circuitry 186 may be differentially coupled to the primary LC tank 116 via a second node 196 and a third node 198. In the depicted embodiment, a gate terminal 193 (e.g., a second terminal) of the first P-channel switch 188 may be coupled to a second terminal 127 of the primary LC tank 116 via the second node 196. Moreover, a gate terminal 199 (e.g., a second terminal) of the second P-channel switch 190 may be coupled to a third terminal 129 of the primary LC tank 116 via the third node 198. The second node 196 may correspond to (e.g., include, be coupled to) a positive output terminal 202 and the third node 198 may correspond to (e.g., include, be coupled to) a negative output terminal 204 of the P-channel VCO 180. The second terminal 127 and the third terminal 129 of the primary LC tank 116 may output the output signal 182 via the positive output terminal 202 and the negative output terminal 204.

A source terminal 189 (e.g., a first terminal) of the first P-channel switch 188 may be coupled to a first terminal 131 of the secondary LC tank circuit 118. A source terminal 195 (e.g., a first terminal) of the second P-channel switch 190 may be coupled to a second terminal 133 of the secondary LC tank circuit 118. The secondary LC tank 118 may be coupled to the power source terminal 124. As mentioned above, the primary LC tank 116 may inductively couple to the secondary LC tank 118 during an operation of the P-channel VCO 180.

The secondary LC tank 118 may receive the bias voltage 126 via the power source terminal 124. In some embodiments, the power source 29 discussed above may be coupled to the power source terminal 124. In some cases, the power source 29 may generate and/or output the bias voltage 126. Alternatively or additionally, the P-channel VCO 180 may receive the bias voltage 126 from any other viable circuit. Moreover, the first P-channel switch 188, the second P-channel switch 190, and/or the primary LC tank 116 may receive any other viable input signal in lieu or additional to the bias voltage 126.

The P-channel current source circuitry 186 may generate and/or provide a DC signal based on receiving the bias voltage 126. For example, the first P-channel switch 188 and the second P-channel switch 190 may form the common drain voltage-controlled current source to generate and/or output the DC signal (e.g., a desired electrical current). The DC signal may have an oscillation frequency of zero, near zero, approximately zero, relatively zero, and/or below a threshold frequency. The LC tank circuitry 104 may generate the output signal 182 and an induced signal 208 (e.g., a second induced signal or an induced voltage) based on receiving the DC signal and/or the bias voltage 126. The output signal 182 and the induced signal 208 may have an oscillation frequency within the resonant frequency range of the LC tank circuitry 104 (e.g., a desired oscillation frequency range).

The primary LC tank 116 may provide the first output signal component 182-1 to the gate terminal 193 of the first P-channel switch 188 and the positive output terminal 202 via the second node 196. The primary LC tank 116 may provide the second output signal component 182-2 to the gate terminal 199 of the second P-channel switch 190 and the negative output terminal 204 via the third node 198. In some embodiments, the LC tank circuitry 104 may generate the output signal 182 with an oscillation frequency corresponding to a carrier signal having the carrier frequency for transmitting outgoing data 60 discussed above. In alternative or additional embodiments, the LC tank circuitry 104 may generate the output signal 182 with an oscillation frequency corresponding to an intermediate or baseband oscillating signal for down-conversion and/or processing of the received signal 80 discussed above.

The primary LC tank 116 may induce the signal 208 in the secondary LC tank circuit 118. The induced signal 208 may include a differential output signal having a first induced signal component 208-1 (e.g., a first signal, a positive signal) and a second induced signal component 208-2 (e.g., a second signal, a negative signal). The secondary LC tank circuit 118 may provide the first induced signal component 208-1 to the source terminal 189 of the first P-channel switch 188. Moreover, the secondary LC tank circuit 118 may provide the second induced signal component 208-2 to the source terminal 195 of the second P-channel switch 190. The first induced signal component 208-1 and the second induced signal component 208-2 may be collectively referred to as the induced signal 208.

The primary LC tank 116 and the secondary LC tank circuit 118 may each include one or more inductors and/or capacitors to synchronize the induced signal 208 with the output signal 182. As such, the primary LC tank 116 may induce a portion of the voltage swing amplitude of the gate terminals 193 and 199 of the P-channel switches 188 and 190 in the respective source terminals 189 and 195. Accordingly, the induced voltage 208 may increase voltage swing amplitudes at the source terminals 189 and 195 of the P-channel switches 188 and 190 based on voltage swing amplitudes of the output signal 182 at the respective gate terminals 193 and 199.

For example, a voltage swing amplitude of the induced signal 208 may correspond to a fraction of a voltage swing amplitude of the output signal 182. The fraction of the output signal 182 may correspond to one-eighth or less, a quarter or less, one-third or less, or half or greater or less of the output signal 182. An oscillation frequency of the induced signal 208 may correspond to an oscillation frequency of the output signal 182. A phase of the first induced signal component 208-1 may correspond to a phase of the first output signal component 182-1. Moreover, a phase of the second induced signal component 208-2 may correspond to a phase of the second output signal component 182-2. Accordingly, the induced voltage 208 may increase voltage swing amplitudes of the source terminals 189 and 195 of the P-channel switches 188 and 190 in synchronization with the output signal 182 at the gate terminals 193 and 199 of the P-channel switches 188 and 190.

With the foregoing in mind, junction voltages (e.g., V_{SG}) of the P-channel switches 188 and 190 may correspond to a differential voltage between voltage swing amplitudes of the respective source terminals 189 and 195 and gate terminals 193 and 199. Moreover, the P-channel switches 188 and 190 may have a junction voltage threshold. The junction voltage threshold of the P-channel switches 188 and 190 may correspond to 0.1 V or less, 0.37 V or less, 0.45 V or less, 0.7 V or less, 1 V or greater or less, and so on, among other possibilities.

In the depicted embodiment, a differential voltage between the induced voltage 208 at the source terminals 189 and 195 of the P-channel switches 188 and 190 and the output signal 182 at the gate terminals 193 and 199 may be equal to or less than the junction voltage threshold. For example, a voltage value (e.g., an instantaneous voltage value) of the output signal 182 at the gate terminals 193 and 199 of the P-channel switches 188 and 190 may correspond to a cumulative value (e.g., an instantaneous cumulative value, an immediate cumulative value) of a voltage swing amplitude of the induced voltage 208 and the differential voltage (e.g., the respective junction voltage, V_{SG}).

As discussed above, the induced voltage 208 may increase voltage swing amplitudes of the source terminals 189 and 195 of the P-channel switches 188 and 190 in synchronization with the output signal 182 at the gate terminals 193 and 199 of the P-channel switches 188 and 190. As such, the voltage swing amplitude of the output signal 182 may be increased without increasing (e.g., expanding) or exceeding (e.g., violating) the junction voltage (e.g., V_{SG}) of the P-channel switches 188 and 190 based on the increased voltage swing amplitude of the respective source terminal 189 and 195. For example, a gate voltage of the first P-channel switch 188 may be increased greater than gate voltages of other VCOs without increasing or exceeding a first junction voltage (e.g., V_{SG1}) of the first P-channel switch 188 based on the induced voltage on the respective source terminal 189 and 195. Similarly, the gate voltage of the second P-channel switch 190 may be increased greater than voltage amplitudes of other VCOs without increasing or exceeding a second junction voltage (e.g., V_{SG2}) of the second P-channel switch 190 based on the induced voltage on the respective source terminal 189 and 195.

Accordingly, the P-channel VCO 180 may generate and/or output the output signal 182 with a greater voltage swing amplitude compared to other VCOs having voltage-controlled current source switches with junction voltages similar (e.g., equal, nearly equal) to that of the P-channel switches 188 and 190. Moreover, the P-channel VCO 180 may have reduced undesired common-mode noises and improved SNR compared to the other VCOs. As mentioned above, the common-mode noises may include a phase noise and/or a flicker noise, among other possibilities. For example, the P-channel VCO 180 may have an increased and/or expanded bandwidth for generating the output signal 182 based on the reduced undesired common-mode noises and/or the improved SNR. As mentioned above, in some embodiments, the common-mode filter 108 may be coupled to ground terminal 136 and to the drain terminals 191 and 197 of the P-channel switches 188 and 190 to reduce the undesired common-mode noises and improve the SNR.

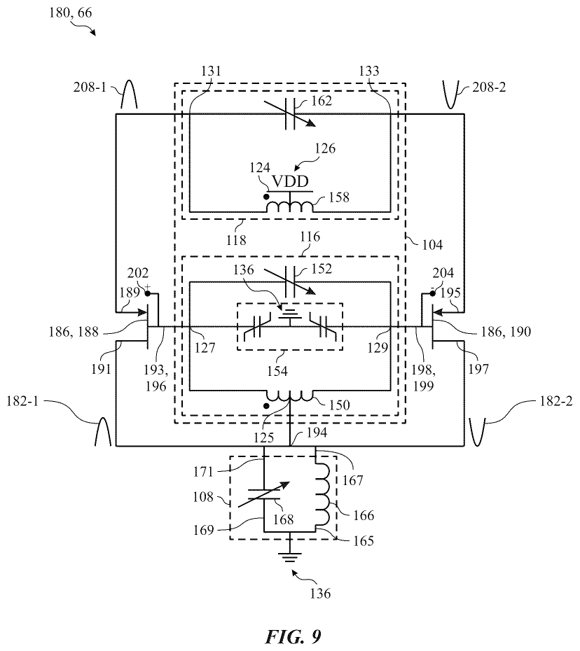

FIG. 9 is a schematic diagram of the P-channel VCO 180, according to embodiments of the present disclosure. The primary LC tank 116 may include the first inductor 150, the first variable capacitor 152, and the capacitor bank 154 including a number of capacitors. The secondary LC tank 118 may include the second inductor 158 and the second variable capacitor 162. Additionally or alternatively, the primary LC tank 116 and/or the secondary LC tank 118 may include switched capacitor circuitry and/or additional capacitor banks, among other things. Moreover, as mentioned above, the P-channel current source circuitry 186 may include the first P-channel switch 188 and the second P-channel switch 190.

The common-mode filter 108 may include the tail inductor 166 (e.g., the first degeneration inductor) and the tail capacitor 168 (e.g., the degeneration capacitor, the variable degeneration capacitor). The tail inductor 166 and/or the tail capacitor 168 may reduce noise of the bias voltage 126 and/or the output signal 182. For example, the tail inductor 166 and/or the tail capacitor 168 may reduce noise of the P-channel VCO 180 and/or the voltage terminal 124 at the ground terminal 136. The first terminal 165 of the tail inductor 166 and the first terminal 169 of the tail capacitor 168 may be coupled to the ground terminal 136. The second terminal 167 of the tail inductor 166 and the second terminal 171 of the tail capacitor 168 may be coupled to the first inductor 150, the drain terminal 191 of the first P-channel switch 188, and the drain terminal 197 of the second P-channel switch 190.

As mentioned above, the drain terminals 191 and 197 of the P-channel switches 188 and 190 and the first terminal 125 of the primary LC tank 116 may be coupled to the ground terminal 136 via (e.g., through) the common-mode filter 108. The first terminal 125 of the primary LC tank 116 may correspond to or be disposed on a winding of the first inductor 150. In the depicted embodiment, the second terminals 167 and 171 of the tail inductor 166 and the tail capacitor 168 may be coupled to drain terminals 191 and 197 of the P-channel switches 188 and 190 and tapped onto (e.g., coupled to) the winding of the first inductor 150.

In some embodiments, the tail inductor 166 and the tail capacitor 168 may be tapped onto a center tap of the first inductor 150 dividing the first inductor 150 into two split (e.g., halved) inductors. Alternatively or additionally, the first decoupling inductor 156 may be tapped onto any other part or portion of the first inductor 150. As such, the first inductor 150 may be coupled to the ground terminal 136 via the tail inductor 166 (e.g., a degeneration inductor) and the tail capacitor 168.

First terminals of the first inductor 150, the first variable capacitor 152, and the capacitor bank 154 may be coupled to the gate terminal 193 of the first P-channel switch 188 via the second node 196. Second terminals of the first inductor 150, the first variable capacitor 152, and the capacitor bank 154 may be coupled to the gate terminal 199 of the second P-channel switch 190 via the third node 198. As mentioned above, the second node 196 may correspond to (e.g., include, be coupled to) a positive output terminal 202 and the third node 198 may correspond to (e.g., include, be coupled to) a negative output terminal 204 of the P-channel VCO 180.

The second inductor 158 may be coupled to the power source terminal 124. In the depicted embodiment, the power source terminal 124 may be tapped onto a winding of the second inductor 158. For example, the power source terminal 124 may be tapped onto a center tap of the second inductor 158 dividing the second inductor 158 into two split (e.g., halved) inductors. Alternatively or additionally, the power source terminal 124 may be tapped onto any other part or portion of the second inductor 158. First terminals of the second inductor 158 and the second variable capacitor 162 may be coupled to the source terminal 189 of the first P-channel switch 188. Second terminals of the second inductor 158 and the second variable capacitor 162 may be coupled to the source terminal 195 of the second P-channel switch 190.

The first inductor 150 and the second inductor 158 may inductively couple with a coupling factor (K) equal to or greater than a first threshold for signals having an oscillation frequency within the resonant frequency range of the LC tank circuitry 104. For example, the signals may include the output signal 102 being generated by the LC tank circuitry 104 and having an oscillation frequency within the resonant frequency range of the LC tank circuitry 104, among other possibilities. The first threshold may be 0.3 or less or greater, 0.4 or greater, 0.44 or greater, 0.5 or greater, 0.72 or greater, 0.76 or greater, 0.9 or greater, or 1, among other possibilities. In different embodiments, the first inductor 150 and the second inductor 158 may have different dimensions corresponding to the resonant frequency range of the LC tank circuitry 104. As such, the first inductor 150 may inductively couple to the second inductor 158 forming a transformer to generate or provide the output signal 182 having an oscillation frequency within the resonant frequency range of the LC tank circuitry 104.

For example, the first inductor 150 may induce the signal 208 in the second inductor 158 and/or the secondary LC tank 118. As discussed above, the induced voltage 208 may increase voltage swing amplitudes of the source terminals 189 and 195 of the P-channel switches 188 and 190 in synchronization with the output signal 182 at the gate terminals 193 and 199 of the P-channel switches 188 and 190. As such, the voltage swing amplitude of the output signal 182 may be increased greater than the voltage swing amplitudes of output signals of other VCOs having voltage-controlled current source switches with similar (e.g., equal, nearly equal) junction voltages. Moreover, the P-channel VCO 180 may have reduced undesired common-mode noises and improved SNR compared to the other VCOs based on the increased voltage swing amplitude of the output signal 182.

The first inductor 150 and the second inductor 158 may inductively uncouple for signals having an oscillation frequency outside the resonant frequency range of the LC tank circuitry 104 based on a coupling factor equal to or less than a second threshold. The signals may be generated and/or received by the LC tank circuitry 104 and may have the undesired oscillation frequency outside the resonant frequency range of the LC tank circuitry 104. For example, the signals may include the common-mode noises, among other possibilities. The second threshold may be 1 or less, 0.9 or less, 0.85 or less, 0.72 or less, 0.64 or less, 0.5 or less, 0.4 or less, 0.2 or less, 0.1 or less, or 0.05 or less, among other possibilities. As such, the first inductor 150 and the second inductor 158 may inductively uncouple for the common-mode noises having the undesired oscillation frequency outside the resonant frequency range of the LC tank circuitry 104. Accordingly, the first inductor 150 and the second inductor 158 may at least partly uncouple and/or isolate the primary LC tank 116 from the secondary LC tank 118 for the common-mode noises.

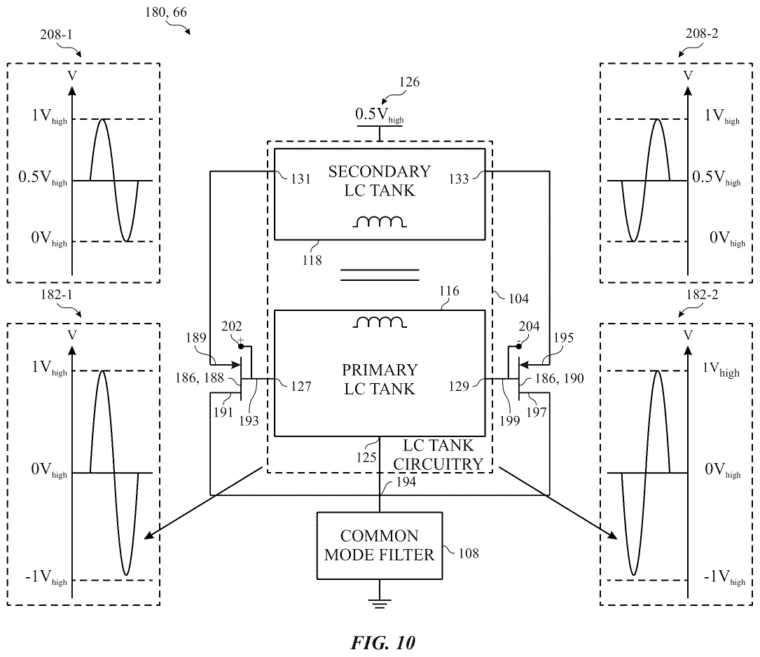

FIG. 10 illustrates an example output signal 182 of the P-channel VCO 180 having an increased voltage swing amplitude based on an increased voltage swing amplitude of the source terminals 189 and 195 of the P-channel switches 188 and 190, according to embodiments of the present disclosure. As discussed above, the first P-channel switch 188 and the second P-channel switch 190 may form the common drain voltage-controlled current source. For example, the P-channel current source circuitry 186 may generate and/or provide a DC signal based on receiving the bias voltage 126. Moreover, the LC tank circuitry 104 may generate the output signal 182 and the induced signal 208 based on receiving the DC signal and/or the bias voltage 126. The output signal 182 may include the first output signal component 182-1 and the second output signal component 182-2. The induced signal 208 may include the first induced signal component 208-1 and the second induced signal component 208-2.

The primary LC tank 116 may provide the first output signal component 182-1 to the positive output terminal 202 and provide the second output signal component 182-2 to the negative output terminal 204. The secondary LC tank circuit 118 may provide the first induced signal component 208-1 to the source terminal 189 of the first P-channel switch 188. Moreover, the secondary LC tank circuit 118 may provide the second induced signal component 208-2 to the source terminal 195 of the second P-channel switch 190. The induced voltage 208 may increase voltage swing amplitudes at the source terminals 189 and 195 of the P-channel switches 188 and 190 based on voltage swing amplitudes of the output signal 182 at the respective gate terminals 193 and 199.

For example, a voltage swing amplitude of the first induced signal component 208-1 may correspond to a fraction (e.g., one-eighth or less, a quarter or less, one-third or less, or half or greater or less) of a voltage swing amplitude of the first output signal component 182-1. As such, the primary LC tank 116 may induce a portion of the voltage swing amplitude of the gate terminal 193 of the first P-channel switch 188 in the source terminal 189 of the first P-channel switch 188. Moreover, a voltage swing amplitude of the second induced signal component 208-2 may correspond to a fraction (e.g., one-eighth or less, a quarter or less, one-third or less, or half or greater or less) of a voltage swing amplitude of the second output signal component 182-2. Accordingly, the primary LC tank 116 may induce a portion of the voltage swing amplitude of the gate terminal 199 of the second P-channel switch 190 in the source terminal 195 of the second P-channel switch 190.

An oscillation frequency of the induced signal 208 may correspond to the oscillation frequency of the output signal 182. A phase of the first induced signal component 208-1 may correspond to that of the first output signal component 182-1. A phase of the second induced signal component 208-2 may correspond to that of the second output signal component 182-2. As such, the induced voltage 208 may increase voltage swing amplitudes of the source terminals 189 and 195 of the P-channel switches 188 and 190 in synchronization with the output signal 182 at the gate terminals 193 and 199 of the P-channel switches 188 and 190.

With the foregoing in mind, the first junction voltage (e.g., V_{SG1}) of the first P-channel switch 188 may correspond to a differential voltage between voltage swing amplitudes of the source terminal 189 and the gate terminal 193 of the first P-channel switch 188. Moreover, the second junction voltage (e.g., V_{SG2}) of the second P-channel switch 190 may correspond to a differential voltage between voltage swing amplitudes of the source terminal 195 and the gate terminal 199 of the second P-channel switch 190. The P-channel switches 188 and 190 may each have a junction voltage threshold associated with the respective junction voltages. The first junction voltage threshold of the first P-channel switch 188 and the second junction voltage threshold of the second P-channel switch 190 may each correspond to 0.1 V or less, 0.37 V or less, 0.45 V or less, 0.7 V or less, 1 V or less, and so on, among other possibilities.

The first junction voltage (e.g., V_{SG1}) of the first N-channel switches 112 may not exceed the first junction voltage threshold. Moreover, the first induced signal component 208-1 may increase voltage swing amplitude of the source terminal 189 of the first N-channel switch in synchronization with the first output signal component 182-1 at the gate terminals 193 of the first P-channel switch 188. As such, the voltage swing amplitude of the first output signal component 182-1 may be increased without increasing (e., expanding) or exceeding (e.g., violating) the first junction voltage (e.g., V_{SG1}). For example, the voltage swing amplitude of the first output signal component 182-1 may be increased by a voltage value corresponding to the voltage value (e.g., an instantaneous voltage value) of the first induced signal component 208-1.

The second junction voltage (e.g., V_{SG2}) of the second N-channel switches 114 may not exceed the second junction voltage threshold. Moreover, the second induced signal component 208-2 may increase voltage swing amplitude of the source terminal 195 of the second N-channel switch in synchronization with the second output signal component 182-2 at the gate terminals 199 of the second P-channel switch 190. As such, the voltage swing amplitude of the second output signal component 182-2 may be increased without increasing (e., expanding) or exceeding (e.g., violating) the second junction voltage (e.g., V_{SG2}). For example, the voltage swing amplitude of the second output signal component 182-2 may be increased by a voltage value corresponding to the voltage value (e.g., an instantaneous voltage value) of the second induced signal component 208-2.

In the depicted embodiment, the bias voltage 126 may have a first voltage value of 0.5 V_{high}. V_{high} (or 1 V_{high}) may correspond to junction voltage thresholds of the P-channel switches 188 and 190. For example, the junction voltage (e.g., V_{SG1}, V_{SG2}) and/or a differential voltage between voltage swing amplitudes of the gate terminals 193 and 199 and the respective source terminals 189 and 195 of the P-channel switches 188 and 190 may be equal to or less than V_{high} (or 1 V_{high}). Other VCOs having voltage-controlled current source switches (e.g., common source voltage-controlled current source switches) with similar (e.g., equal, nearly equal) junction voltages may generate the output signal 182 with a voltage swing amplitude between 0 V_{high} and −1 V_{high}. The P-channel VCO 180 may generate the output signal 182 with a voltage swing amplitude between −1 V_{high} and 1 V_{high}. That is, the P-channel VCO 180 may generate the output signal 182 with an increased voltage swing amplitude and/or expanded (e.g., doubled) voltage swing amplitude range.

By way of example, the LC tank circuitry 104 may generate the first induced signal component 208-1 and the second induced signal component 208-2 having a voltage swing amplitude of 1 V_{high} between a low voltage swing amplitude of 0 V_{high} and a high voltage swing amplitude of 1 V_{high} swinging around (e.g., centered at) the first voltage value (e.g., 0.5 V_{high}). The first induced signal component 208-1 may be inversed compared to the second induced signal component 208-2. Moreover, the LC tank circuitry 104 may generate the first output signal component 182-1 and the second output signal component 182-1 having a voltage swing amplitude of 2 V_{high} (e.g., instead of 1 V_{high}) between a low voltage swing amplitude of-1 V_{high} and a high voltage swing amplitude of 1 V_{high} swinging around (e.g., centered at) 0 V_{high}.

The first induced signal component 208-1 may be in-phase (e.g., nearly in-phase) with the first output signal component 182-1. The second induced signal component 208-2 may be in-phase (e.g., nearly in-phase) with the second output signal component 182-2. Accordingly, the P-channel VCO 180 may generate and/or output the output signal 182 with a greater voltage swing amplitude, reduced undesired common-mode noises, improved SNR, and/or increased and/or expanded bandwidth compared to other VCOs.

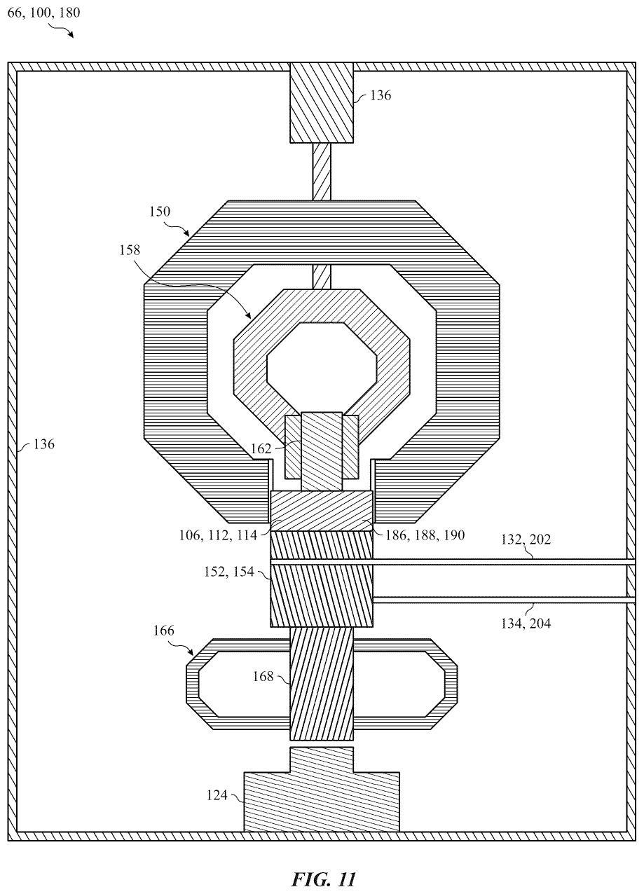

FIG. 11 is a layout of the VCO 66, according to embodiments of the present disclosure. The layout of the VCO 66 may include the N-channel VCO 100 or the P-channel VCO 180. In the depicted embodiment, the LC tank circuitry 104, the current source circuitry 106 or 186, the common-mode filter 108, the power source terminal 124, and the ground terminal 136 are shown. The LC tank circuitry 104 may include the inductors 150 and 158, the variable capacitors 152 and 162, and the capacitor bank 154. The common-mode filter 108 may include the tail inductor 166 and the tail capacitor 168.

In different embodiments, the first inductor 150 and the second inductor 158 may have different dimensions corresponding to the resonant frequency range of the LC tank circuitry 104. The first inductor 150 may inductively couple to the second inductor 158 forming a transformer to generate or provide the output signal 102 or 182 having an oscillation frequency within the resonant frequency range of the LC tank circuitry 104. The LC tank circuitry 104 may output the output signal 102 via the output terminals 132 and 134. Alternatively or additionally, the LC tank circuitry 104 may output the output signal 182 via the output terminals 202 and 204.

As discussed above, the N-Channel switches 112 and 114 of the N-channel current source circuitry 106 may form the common drain voltage-controlled current source circuitry. Moreover, the P-channel switches 188 and 190 of the P-channel current source circuitry 186 may form the common drain voltage-controlled current source circuitry. The VCO 66 including the common drain voltage-controlled current source circuitry may occupy a similar area compared to other VCOs including other voltage-controlled current source circuitry (e.g., common source voltage-controlled current source circuitry).

In some cases, the VCO 66 may include switches 112, 114, 188, and/or 190 with junction voltages equal to (e.g., nearly equal to, approximately equal to) that of one or more other VCOs while generating the output signal 102 and/or 182 with increased voltage amplitude swings compared to such other VCOs. In alternative or additional cases, the VCO 66 may include switches 112, 114, 188, and/or 190 with junction voltages less than that of one or more other VCOs while generating the output signal 102 and/or 182 with equal (e.g., nearly equal, approximately equal) voltage amplitude swings compared to such other VCOs. As such, the VCO 66 may include switches 112, 114, 188, and/or 190 occupying the same (e.g., nearly the same, approximately the same) area or less area compared to other VCOs.

Moreover, in some cases, the VCO 66 may not include additional circuitry (e.g., filters) to implement the common drain voltage-controlled current source circuitry compared to other VCOs including other voltage-controlled current source circuitry (e.g., common source voltage-controlled current source circuitry). Accordingly, the VCO 66 may be improved based on generating the output signal 102 and/or 182 with increased voltage amplitude swing while occupying the same (e.g., nearly the same, approximately the same) area compared to other VCOs.

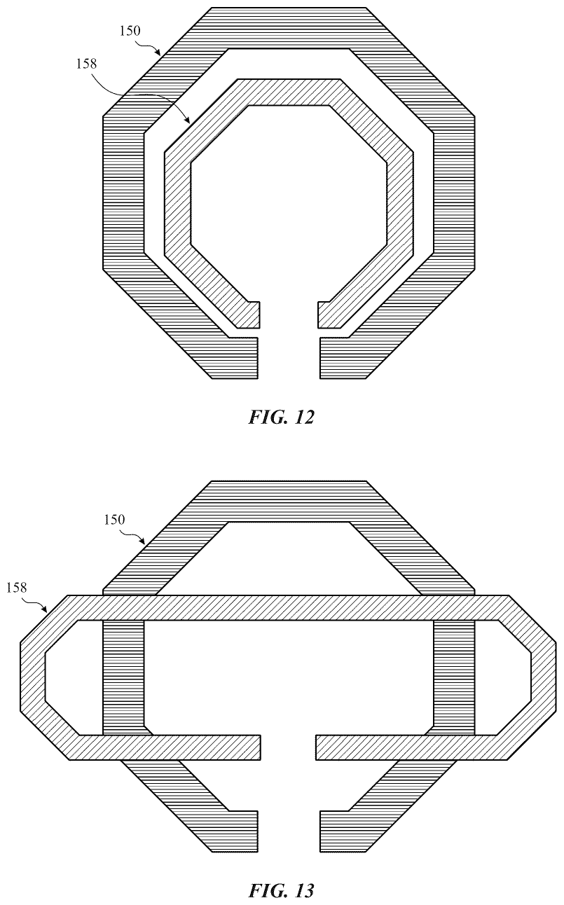

FIG. 12 illustrates a concentric embodiment of the inductors 150 and 158 of the VCO 66, according to embodiments of the present disclosure. In the depicted embodiment, the second inductor 158 may be fully enclosed by the first inductor 150. For example, the second inductor 158 may be disposed concentrically within the first inductor 150, at a same layer or overlaid over or under the first inductor 150, within a threshold proximity of the second inductor 158. The threshold proximity may be 1 picometer or less, 100 nano meter (nm) or less, 57 nm or less, 8 nm or less, 674 millimeter (mm) or less, 94 mm or less, 10 mm or less, 0.1 mm or less, among other possibilities.

FIG. 13 illustrates a partially overlapping embodiment of the inductors 150 and 158 of the VCO 66, according to embodiments of the present disclosure. The second inductor 158 may be overlaid over or under the first inductor 150 with partially overlapping boundary, for example, on or into a printed circuit board (PCB), among other possibilities. In some cases, the first inductor 150 and the second inductor 158 may occupy an area corresponding to an area of either of the first inductor 150 or the second inductor 158 that is less than the area occupied by the first inductor 150 and the second inductor 158 disposed with a different disposition. For example, the first inductor 150 and the second inductor 158 may occupy an area corresponding to a portion of the area occupied by the first inductor 150 and the second inductor 158 being disposed side-by-side.

With the foregoing in mind, it should be appreciated that the layouts of FIGS. 12 and 13 are provided as an example and the VCO 66 may have any other viable layout and/or variations of the layout. It should be appreciated that in different embodiments, the first inductor 150 and the second inductor 158 may have different dimensions forming a transformer to generate or provide the output signal 102 or 182. For example, the inductors 150 and 158 may each have a circular shape or a viable polygonal shape (e.g., triangular, rectangular, pentagonal, hexagonal, and so on).

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function]. . . ,” it is intended that such elements are to be interpreted under 35 U.S.C. 116(f). However, for any claims containing elements designated in any other manner, it is intended that such elements are not to be interpreted under 35 U.S.C. 116(f).

What is claimed is:

1. An electronic device comprising:
one or more antennas; and
a voltage-controlled oscillator (VCO) coupled to the one or more antennas, the VCO comprising
a first inductor,
a second inductor, and
a first switch having
a first terminal tapped onto a winding of the first inductor,
a second terminal coupled to a first terminal of the first inductor, and
a third terminal coupled to a first terminal of the second inductor.

2. The electronic device of claim 1, wherein the VCO comprises a second switch having
a first terminal tapped onto the winding of the first inductor,
a second terminal coupled to a second terminal of the first inductor, and
a third terminal coupled to a second terminal of the second inductor.

3. The electronic device of claim 2, wherein the VCO comprises a first capacitor having
a first terminal coupled to the second terminal of the first switch, and
a second terminal coupled to the second terminal of the second switch.

4. The electronic device of claim 2, wherein the VCO comprises a second capacitor having
a first terminal coupled to the third terminal of the first switch, and
a second terminal coupled to the third terminal of the second switch.

5. The electronic device of claim 1, wherein the first terminal of the first switch and the winding of the first inductor are coupled to a voltage source terminal of the VCO.

6. The electronic device of claim 5, wherein the VCO comprises a common-mode filter coupled to the voltage source terminal, the first terminal of the first switch and the winding of the first inductor coupled to the voltage source terminal via the common-mode filter.

7. The electronic device of claim 6, wherein the common-mode filter comprises
a degeneration inductor having a first terminal coupled to the voltage source terminal and a second terminal coupled to the first terminal of the first switch and the winding of the first inductor, and
a degeneration capacitor having a first terminal coupled to the voltage source terminal and a second terminal coupled to the first terminal of the first switch and the winding of the first inductor.

8. The electronic device of claim 1, wherein a winding of the second inductor is coupled to a ground terminal.

9. The electronic device of claim 1, wherein the first terminal is tapped onto a center tap of the winding of the first inductor.

10. A voltage-controlled oscillator (VCO) comprising:
a first inductor-capacitor tank coupled to a voltage source terminal, a first output terminal of the VCO, and a second output terminal of the VCO;
a first switch having a first terminal coupled to the voltage source terminal and a second terminal coupled to the first output terminal;
a second switch having a first terminal coupled to the voltage source terminal and a second terminal coupled to the second output terminal; and
a second inductor-capacitor tank coupled to a third terminal of the first switch and a third terminal of the second switch.

11. The VCO of claim 10, wherein the first inductor-capacitor tank comprises a first inductor and a first capacitor, the first inductor being coupled to the voltage source terminal.

12. The VCO of claim 11, wherein a first terminal of the first inductor is coupled to the first output terminal and a second terminal of the first inductor is coupled to the second output terminal.

13. The VCO of claim 11, wherein the second inductor-capacitor tank comprises a second inductor and a second capacitor, the first inductor configured inductively couple to the second inductor.

14. The VCO of claim 10, comprising a common-mode filter coupled to the voltage source terminal, the first inductor-capacitor tank, the first terminal of the first switch, and the first terminal of the second switch being coupled to the voltage source terminal via the common-mode filter.

15. A transceiver comprising:
a first inductor-capacitor tank coupled to a voltage source terminal, a first output terminal, and a second output terminal;
a second inductor-capacitor tank; and
a first switch having
a first terminal coupled to the voltage source terminal,
a second terminal coupled to the first output terminal, and
a third terminal coupled to the second inductor-capacitor tank.

16. The transceiver of claim 15, comprising a second switch, a first terminal of the second switch coupled to the voltage source terminal, a second terminal of the second switch coupled to the second output terminal, and a third terminal of the second switch coupled to the second inductor-capacitor tank.

17. The transceiver of claim 15, wherein the first inductor-capacitor tank comprises a first inductor coupled to the first output terminal and the second output terminal, and the second inductor-capacitor tank comprises a second inductor coupled to the third terminal of the first switch.

18. The transceiver of claim 17, wherein the second inductor is disposed concentrically within the first inductor.

19. The transceiver of claim 17, wherein the second inductor is overlaid on the first inductor with a partially overlapping boundary.

20. The transceiver of claim 15, comprising a mixer coupled to the first output terminal and the second output terminal, the mixer configured to generate a combined signal based on an output signal of the first inductor-capacitor tank.
